(19) United States
(12) Patent Application Publication
(10) Pub. No.: US 2021/0182166 A1
(43) Pub. Date: Jun. 17, 2021

(54) ZONED NAMESPACE MANAGEMENT OF NON-VOLATILE STORAGE DEVICES

(71) Applicant: Western Digital Technologies, Inc., San Jose, CA (US)

(72) Inventors: Judah Gamliel Hahn, 24 Eretz Yemini Street (IL); Idan Alrod, 8th Atir Yeda Street (IL); Ariel Navon, 307 Nahal Shilo St POB 230 (IL); Eran Sharon, Arthur Rubinshtein 6 (IL); Shay Benisty, Beer Sheva (IL); Joe Meza, Aliso Viejo, CA (US)

(73) Assignee: Western Digital Technologies, Inc., San Jose, CA (US)

(21) Appl. No.: 16/712,659

(22) Filed: Dec. 12, 2019

(51) Int. Cl. G06F 11/30; G06F 11/07; G06F 11/10; G06F 3/06; G11C 16/16; G11C 16/34

(52) U.S. Cl. CPC G06F 11/3034; G06F 11/3086; G06F 11/3058; G06F 11/076; G11C 16/3495; G06F 3/0619; G06F 3/064; G06F 3/0688; G11C 16/16; G06F 11/102

(57) ABSTRACT

This disclosure relates to an apparatus including a zone manager to manage memory allocation and behavior under a Zoned Namespaces (ZNS) implementation. The zone manager may include a monitor circuit, an evaluation circuit, and a signaling circuit. The monitor circuit is configured to monitor a zone metric for each zone of a non-volatile storage device. The evaluation circuit is configured to determine health for each zone based on the zone metric. The signaling circuit is configured to notify a host of the zone health for one or more zones in response to the zone metric for the zone(s) satisfying an alert threshold.

### BACKGROUND

The Zoned Namespaces (ZNS) standard is a new standard in storage management, in which the storage device is restricted to writing exclusively in sequential order within zones. ZNS is intended to reduce device-side write amplification and over-provisioning by aligning host write patterns with internal device geometry and reducing the need for device-side writes which are not directly linked to a host write of host data. More details describing this concept can be found at the website zonedstorage.io.

“Zone” refers to a set of memory cells configured such that memory cells are only written in response to a write command from a host, data blocks of memory cells are randomly addressable, and all the memory cells in a zone are erased in response to an erase operation. The set of memory cells that make up a zone may be configured in a variety of ways.

In one embodiment, a zone comprises memory cells of one erase block, such as a physical erase block, from each plane of two or more memory die. In one embodiment, a zone comprises a set of logical erase blocks, each logical erase block comprising memory cells of one physical erase block from each physical plane of two or more memory die of a non-volatile memory device.

In embodiments that implement one of the zoned storage device standards for a zone, such as ZBC, ZNS, or OpenChannel, the memory cells of a zone are managed and configured such that zones are only written to in a sequential order, with a write pointer that identifies the physical location for a subsequent write operation. In addition, data in a zone cannot be directly overwritten. The zone must first be erased using a special command (zone reset). (See introduction page on zonedstorage.io website Edited).

Zones may be implemented using various recording and media technologies. A common form of zoned storage today uses the SCSI Zoned block Commands (ZBC) and Zoned ATA Commands (ZAC) interfaces on Shingled Magnetic Recording (SMR) HDDs. ZBC and ZAC enable a zoned block storage model; SMR technology enables continued areal density growth to meet the demands for expanding data needs and may use the zoned block access model. Id. With edits

Solid State Disks (SSD) storage devices can also implement a zoned interface to reduce write amplification, reduce the device DRAM needs and improve quality of service at scale. Id. Edited.

Cross temperature is a common phenomenon in NAND flash memories that is related to temperature differences between storage operations. “Cross temperature” refers to a condition in which a temperature of a memory cell at a time when the memory cell is read/sensed is different from a temperature of the same memory cell when the memory cell was written to (programmed). In certain types of non-volatile memory media, such as NAND memory cells when the difference between temperature when the memory cell is written and when is it read is sufficiently high, the memory cell is unreadable (a read command results in an error). Current, non-volatile storage device have countermeasures such that data stored in a non-volatile memory subject to a cross temperature can be read, however the non-volatile storage device should detect a cross temperature condition such that these countermeasures can be employed.

This cross-temperature phenomenon is known to produce both shifting of the threshold voltage distributions, as well as widening of the threshold voltage distributions. The shifting issue can be handled with reasonable success (e.g., by detecting the cross temperature per block and applying a corresponding varying read threshold compensation) the shifting phenomena is still considered a challenge to the error correction code and the memory management. The shifting phenomena may be related to varying sensitivity of the different NAND cells to the cross temperature (and hence different cells will response with a different read voltage shift to a certain cross temperature).

In current approaches for ZNS implementation, the cross-temperature condition and physical block health are not taken into account. Since multiple zones are managed in parallel and may be kept open for a significant time span, cross temperature effects may be significant. Because block health is not taken into account during the allocation of physical blocks to different zones, zones may be allocated with a health imbalance, causing performance diversity and impacting fulfillment of quality-of-service requirements. Hence a ZNS system strategy is needed to deal with zone-level problems that may arise, especially due to the large number of open zones, which is an inherent property of ZNS based memory systems.

### BRIEF SUMMARY

This disclosure relates to an apparatus comprising a zone manager to manage memory allocation and behavior under a Zoned Namespaces (ZNS) implementation. The zone manager may comprise a monitor circuit, an evaluation circuit, and a signaling circuit. The monitor circuit may be configured to monitor a zone metric for each zone of a non-volatile storage device. The evaluation circuit may be configured to determine health for each zone based on the zone metric. The signaling circuit may be configured to notify a host of the zone health for one or more zones in response to the zone metric for the zone(s) satisfying an alert threshold.

This disclosure further relates to a storage system comprising volatile memory and a non-volatile memory array that includes a plurality of memory dies. The system may also comprise a storage controller coupled to the volatile memory and the non-volatile memory array. The storage controller may comprise a zone manager configured to interface with a host and to manage a plurality of zones within the non-volatile memory array by way of a zoned storage device standard. The storage controller may also comprise a temperature manager. The temperature manager may be configured to monitor a cross temperature metric for each physical erase block of each zone using at least one temperature sensor coupled to each memory die. The temperature manager may be further configured to notify the zone manager in response to the cross-temperature metric for one or more of the zones satisfying an alert threshold. Finally, the storage controller may comprise a health manager. The health manager may be configured to monitor a block health metric for each physical erase block of each zone and to notify the zone manager in response to the block health metric for one or more of the zones satisfying the alert threshold. The zone manager may be further configured to determine a zone metric based at least in part on the cross-temperature metric from the temperature manager and/or the block health metric from the health manager. The zone manager may be configured to implement one or more countermeasures on one or more zones in response to a report of the zone metric to the host configured to manage the zones.

Finally, this disclosure relates to a method. The method comprises monitoring a zone metric for a zone of a non-volatile storage device. The method further comprises notifying a host of the zone metric, in response to the zone metric satisfying an alert threshold. Finally, the method comprises implementing a countermeasure in response to a countermeasure command from the host.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a storage system 100 in accordance with one embodiment.

FIG. 2 is a block diagram of an example storage device 102 in one embodiment.

FIG. 3 illustrates a logical address space with zoned storage allocation 300 in accordance with one embodiment.

FIG. 4 illustrates a ZNS storage device 400 in accordance with one embodiment.

FIG. 5 illustrates a ZNS storage system 500 in accordance with one embodiment.

FIG. 6 illustrates a storage controller 104 in accordance with one embodiment.

FIG. 7 illustrates a ZNS storage system 700 in accordance with one embodiment.

FIG. 8 is an example block diagram of a computing device 800 that may incorporate certain embodiments.

FIG. 9 illustrates a routine in accordance with one embodiment.

### DETAILED DESCRIPTION

This disclosure relates to solutions for monitoring and adjusting for zone-level problems, such as the cross temperature disturb in Zoned Namespace (ZNS) devices and variations in physical health of memory blocks. In certain embodiments, the solution determines a zone metric. In one embodiment, the zone metric may be used to determine a zone health. A zone-level block health metric and cross temperature metric may be produced and reported to a host such that memory usage may be optimized through ZNS-based memory management strategies.

“Memory cell” refers to a type of storage media configured to represent one or more binary values by way of a determinable physical characteristic of the storage media when the storage media is sensed, read, or detected to determine what binary value(s) was last stored in the memory cell. Memory cell and storage cell are used interchangeably herein.

In one example, a zone temperature tracking table may be maintained, and if an alert threshold is met between the operating temperature and the temperature at write time, a report to the host may be made. In response to an alert threshold being satisfied, the host may elect to close the zone, initiate a cooling process, or fix the zone by performing a relocation operation. “Alert threshold” refers to a type of threshold that is predefined such that when a value, rating, or condition satisfies the alert threshold, the system, apparatus, or method is configured to signal either a problem or error or a potential for an imminent problem or error state. “Threshold” refers to a level, point, or value above which a condition is true or will take place and below which the condition is not true or will not take place. (“threshold.” Merriam-Webster.com. Merriam-Webster, 2019. Web. 14 Nov. 2019. Edited)

The block health metric may be used to group different physical erase blocks into zones to achieve balanced zones in which physical erase block are allocated to zones such that zones have a similar mean health, or to group blocks into zones with minimum health difference between blocks. Zones may be used and managed in other ways based on zone metrics, as described in further detail with regard to the figures below.

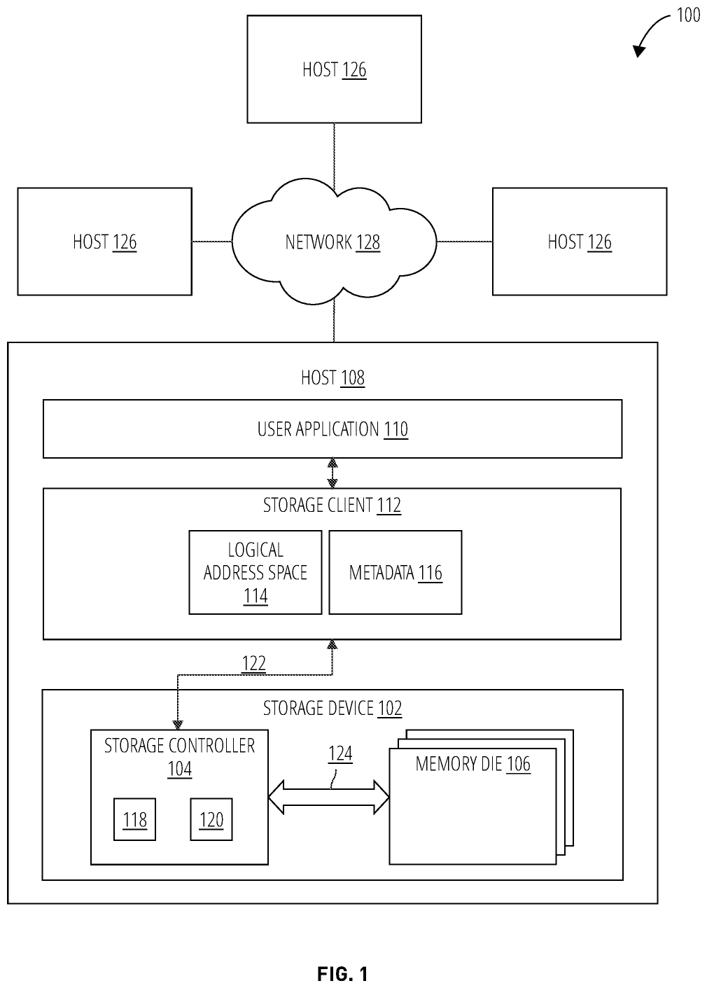

FIG. 1 is a schematic block diagram illustrating one embodiment of a storage system 100 that includes a zoned storage device in accordance with the disclosed solution. The storage system 100 comprises a storage device 102, a storage controller 104, a memory die 106, a host 108, a user application 110, a storage client 112, a logical address space 114, a metadata 116, a FLASH translation layer 118, an address mapping table 120, a data bus 122, a bus 124, at least one host 126, and a network 128.

The storage system 100 includes at least one storage device 102, comprising a storage controller 104 and one or more memory die 106, connected by a bus 124. In some embodiments, the storage system 100 may include two or more memory devices. “Storage controller” refers to any hardware, device, component, element, or circuit configured to manage data operations on non-volatile memory media, and may comprise one or more processors, programmable processors (e.g., FPGAs), ASICs, micro-controllers, or the like. In some embodiments, the storage controller is configured to store data on and/or read data from non-volatile memory media, to transfer data to/from the non-volatile memory device(s), and so on.

“Memory die” refers to a small block of semiconducting material on which a given functional circuit is fabricated. Typically, integrated circuits are produced in large batches on a single wafer of electronic-grade silicon (EGS) or other semiconductor (such as GaAs) through processes such as photolithography. The wafer is cut (diced) into many pieces, each containing one copy of the circuit. Each of these pieces is called a die. (Search “die” on Wikipedia.com Oct. 9, 2019. Accessed Nov. 18, 2019.)

A memory die is a die that includes a functional circuit for operating as a non-volatile memory media and/or a non-volatile memory array. “Non-volatile memory media” refers to any hardware, device, component, element, or circuit configured to maintain an alterable physical characteristic used to represent a binary value of zero or one after a primary power source is removed. Examples of the alterable physical characteristic include, but are not limited to, a threshold voltage for a transistor, an electrical resistance level of a memory cell, a current level through a memory cell, a magnetic pole orientation, a spin-transfer torque, and the like.

The alterable physical characteristic is such that, once set, the physical characteristic stays sufficiently fixed such that when a primary power source for the non-volatile memory media is unavailable the alterable physical characteristic can be measured, detected, or sensed, when the binary value is read, retrieved, or sensed. Said another way, non-volatile memory media is a storage media configured such that data stored on the non-volatile memory media is retrievable after a power source for the non-volatile memory media is removed and then restored. Non-volatile memory media may comprise one or more non-volatile memory elements, which may include, but are not limited to: chips, packages, planes, memory die, and the like.

Examples of non-volatile memory media include but are not limited to: ReRAM, Memristor memory, programmable metallization cell memory, phase-change memory (PCM, PCME, PRAM, PCRAM, ovonic unified memory, chalcogenide RAM, or C-RAM), NAND flash memory (e.g., 2D NAND flash memory, 3D NAND flash memory), NOR flash memory, nano random access memory (nano RAM or NRAM), nanocrystal wire-based memory, silicon-oxide based sub-10 nanometer process memory, graphene memory, Silicon-Oxide-Nitride-Oxide-Silicon (SONOS), programmable metallization cell (PMC), conductive-bridging RAM (CBRAM), magneto-resistive RAM (MRAM), magnetic storage media (e.g., hard disk, tape), optical storage media, or the like.

While the non-volatile memory media is referred to herein as “memory media,” in various embodiments, the non-volatile memory media may more generally be referred to as non-volatile memory. Because non-volatile memory media is capable of storing data when a power supply is removed, the non-volatile memory media may also be referred to as a recording media, non-volatile recording media, storage media, storage, non-volatile memory, volatile memory medium, non-volatile storage medium, non-volatile storage, or the like.

In certain embodiments, data stored in non-volatile memory media is addressable at a block level which means that the data in the non-volatile memory media is organized into data blocks that each have a unique logical address (e.g., LBA). In other embodiments, data stored in non-volatile memory media is addressable at a byte level which means that the data in the non-volatile memory media is organized into bytes (8 bits) of data that each have a unique address, such as a logical address. One example of byte addressable non-volatile memory media is storage class memory (SCM).

“Non-volatile memory array” refers to a set of non-volatile storage cells (also referred to as memory cells or non-volatile memory cells) organized into an array structure having rows and columns. A memory array is addressable using a row identifier and a column identifier.

Each storage device 102 may include two or more memory die 106, such as flash memory, nano random-access memory (“nano RAM or NRAM”), magneto-resistive RAM (“MRAM”), dynamic RAM (“DRAM”), phase change RAM (“PRAM”), etc. In further embodiments, the data storage device 102 may include other types of non-volatile and/or volatile data storage, such as dynamic RAM (“DRAM”), static RAM (“SRAM”), magnetic data storage, optical data storage, and/or other data storage technologies.

The storage device 102, also referred to herein as a storage device, may be a component within a host 108 as depicted in here, and may be connected using a data bus 122, such as a peripheral component interconnect express (“PCI-e”) bus, a Serial Advanced Technology Attachment (“serial ATA”) bus, or the like. In another embodiment, the storage device 102 is external to the host 108 and is connected, a universal serial bus (“USB”) connection, an Institute of Electrical and Electronics Engineers (“IEEE”) 1394 bus (“FireWire”), or the like. In other embodiments, the storage device 102 is connected to the host 108 using a peripheral component interconnect (“PCI”) express bus using external electrical or optical bus extension or bus networking solution such as InfiniB and or PCI Express Advanced Switching (“PCIe-AS”), or the like. “Host” refers to any computing device or computer device or computer system configured to send and receive storage commands. Examples of a host include, but are not limited to, a computer, a laptop, a mobile device, an appliance, a virtual machine, an enterprise server, a desktop, a tablet, a main frame, and the like.

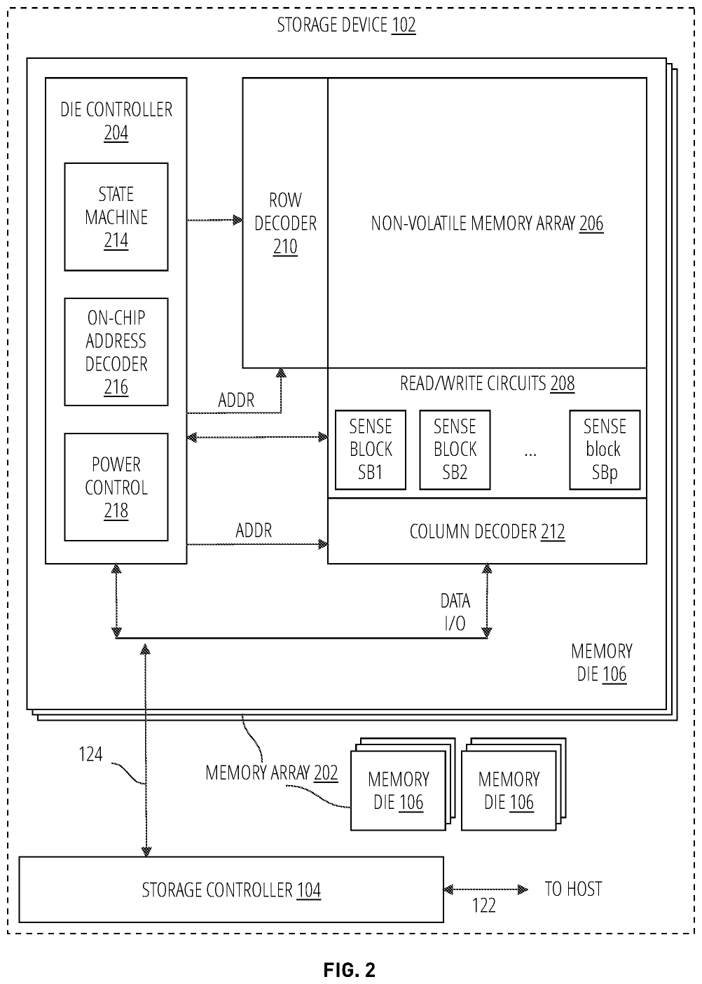

In various embodiments, the storage device 102 may be in the form of a dual-inline memory module (“DIMM”), a daughter card, or a micro-module. In another embodiment, the storage device 102 is a component within a rack-mounted blade. In another embodiment, the storage device 102 is contained within a package that is integrated directly onto a higher-level assembly (e.g., mother board, laptop, graphics processor). In another embodiment, individual components comprising the storage device 102 are integrated directly onto a higher-level assembly without intermediate packaging. The storage device 102 is described in further detail with regard to FIG. 2.

In a further embodiment, instead of being connected directly to the host 108 as DAS, the data storage device 102 may be connected to the host 108 over a data network. For example, the data storage device 102 may include a storage area network (“SAN”) storage device, a network attached storage (“NAS”) device, a network share, or the like. In one embodiment, the storage system 100 may include a data network, such as the Internet, a wide area network (“WAN”), a metropolitan area network (“MAN”), a local area network (“LAN”), a token ring, a wireless network, a fiber channel network, a SAN, a NAS, ESCON, or the like, or any combination of networks. A data network may also include a network from the IEEE 802 family of network technologies, such Ethernet, token ring, Wi-Fi, Wi-Max, and the like. A data network may include servers, switches, routers, cabling, radios, and other equipment used to facilitate networking between the host 108 and the data storage device 102.

The storage system 100 includes at least one host 108 connected to the storage device 102. Multiple hosts 108 may be used and may comprise a server, a storage controller of a storage area network (“SAN”), a workstation, a personal computer, a laptop computer, a handheld computer, a supercomputer, a computer cluster, a network switch, router, or appliance, a database or storage appliance, a data acquisition or data capture system, a diagnostic system, a test system, a robot, a portable electronic device, a wireless device, or the like. In another embodiment, a host 108 may be a client and the storage device 102 operates autonomously to service data requests sent from the host 108. In this embodiment, the host 108 and storage device 102 may be connected using a computer network, system bus, Direct Attached Storage (DAS) or other communication means suitable for connection between a computer and an autonomous storage device 102.

The depicted embodiment shows a user application 110 in communication with a storage client 112 as part of the host 108. In one embodiment, the user application 110 is a software application operating on or in conjunction with the storage client 112.

“Storage client” refers to any hardware, software, firmware, or logic component or module configured to communicate with a storage device in order to use storage services. Examples of a storage client include, but are not limited to, operating systems, file systems, database applications, a database management system (“DBMS”), server applications, a server, a volume manager, kernel-level processes, user-level processes, applications, mobile applications, threads, processes, and the like. “Hardware” refers to functional elements embodied as analog and/or digital circuitry. “Software” refers to logic implemented as processor-executable instructions in a machine memory (e.g., read/write volatile memory media or non-volatile memory media). “Firmware” refers to logic embodied as processor-executable instructions stored on volatile memory media and/or non-volatile memory media.

The storage client 112 manages files and data and utilizes the functions and features of the storage controller 104 and associated memory die 106. Representative examples of storage clients include, but are not limited to, a server, a file system, an operating system, a database management system (“DBMS”), a volume manager, and the like. The storage client 112 is in communication with the storage controller 104 within the storage device 102. In some embodiments, the storage client 112 may include remote storage clients operating on hosts 126 or otherwise accessible via the network 128. Storage clients may include, but are not limited to operating systems, file systems, database applications, server applications, kernel-level processes, user-level processes, applications, and the like.

The storage client 112 may present a logical address space 114 to the host 108 and/or user application 110. “Logical address space” refers to a logical representation of memory resources. The logical address space may comprise a plurality (e.g., range) of logical addresses. The logical address space 114 may comprise a plurality (e.g., range) of logical addresses. As used herein, a logical address refers to any identifier for referencing a memory resource (e.g., data), including, but not limited to: a logical block address (LBA), cylinder/head/sector (CHS) address, a file name, an object identifier, an inode (index node), a Universally Unique Identifier (UUID), a Globally Unique Identifier (GUID), a hash code, a signature, an index entry, a range, an extent, or the like.

“Logical address” refers to any identifier for referencing a memory resource (e.g., data), including, but not limited to: a logical block address (LBA), cylinder/head/sector (CHS) address, a file name, an object identifier, an inode, a Universally Unique Identifier (UUID), a Globally Unique Identifier (GUID), a hash code, a signature, an index entry, a range, an extent, or the like. A logical address does not indicate the physical location of data on the storage media, but is an abstract reference to the data.

“Logical block address” refers to a value used in a block storage device to associate each of n logical blocks available for user data storage across the storage media with an address. In certain block storage devices, the logical block addresses (LBAs) may range from 0 to n per volume or partition. In block storage devices, each LBA maps directly to a particular data block, and each data block maps to a particular set of physical sectors on the physical storage media.

A device driver for the host 108 (and/or the storage client 112) may maintain metadata 116 within the storage client 112, such as a logical to physical address mapping structure, to map logical addresses of the logical address space 114 to storage locations on the memory die 106. A device driver may be configured to provide storage services to one or more storage clients.

The storage controller 104 may comprise the FLASH translation layer 118 and address mapping table 120. “FLASH translation layer” refers to logic in a FLASH memory device that includes logical-to-physical address translation providing abstraction of the logical block addresses used by the storage client and the physical block addresses at which the storage controller stores data. The logical-to-physical translation layer maps logical block addresses (LBAs) to physical addresses of data stored on solid-state storage media. This mapping allows data to be referenced in a logical block address space using logical identifiers, such as a block address. A logical identifier does not indicate the physical location of data on the solid-state storage media but is an abstract reference to the data.

The FLASH translation layer 118 receives the processed data as well as one or more control signals to determine the FLASH translation layer queue depth. The FLASH translation layer 118 may interact via control signals with the address mapping table 120 to determine an appropriate physical address to send data and commands to the memory die 106 and the volatile memory. In one embodiment, the FLASH translation layer 118 also receives the data outputs from the memory die 106.

“Address mapping table” refers to a data structure that associates logical block addresses with physical addresses of data stored on a non-volatile memory array. The table may be implemented as an index, a map, a b-tree, a content addressable memory (CAM), a binary tree, and/or a hash table, and the like. The address mapping table 120 stores address locations for data blocks on the storage device 102 to be utilized by the FLASH translation layer 118. Specifically, the FLASH translation layer 118 searches the address mapping table 120 to determine if a logical block address included in the storage command, has an entry in the address mapping table 120. If so, the physical address associated with the logical block address is used to direct the storage operation on the memory die 106.

“Data block” refers to a smallest physical amount of storage space on physical storage media that is accessible, and/or addressable, using a storage command. The physical storage media may be volatile memory media, non-volatile memory media, persistent storage, non-volatile storage, flash storage media, hard disk drive, or the like. Certain conventional storage devices divide the physical storage media into volumes or logical partitions (also referred to as partitions). Each volume or logical partition may include a plurality of sectors. One or more sectors are organized into a block (also referred to as a data block). In certain storage systems, such as those interfacing with the Windows® operating systems, the data blocks are referred to as clusters. In other storage systems, such as those interfacing with UNIX, Linux, or similar operating systems, the data blocks are referred to simply as blocks. A data block or cluster represents a smallest physical amount of storage space on the storage media that is managed by a storage controller. A block storage device may associate n data blocks available for user data storage across the physical storage media with a logical block address (LBA), numbered from 0 to n. In certain block storage devices, the logical block addresses may range from 0 to n per volume or logical partition. In conventional block storage devices, a logical block address maps directly to one and only one data block.

“Storage operation” refers to an operation performed on a memory cell in order to change, or obtain, the value of data represented by a state characteristic of the memory cell. Examples of storage operations include but are not limited to reading data from (or sensing a state of) a memory cell, writing (or programming) data to a memory cell, and/or erasing data stored in a memory cell.

In one embodiment, the storage system 100 includes one or more clients connected to one or more hosts 126 through one or more computer networks 128. A host 126 may be a server, a storage controller of a SAN, a workstation, a personal computer, a laptop computer, a handheld computer, a supercomputer, a computer cluster, a network switch, router, or appliance, a database or storage appliance, a data acquisition or data capture system, a diagnostic system, a test system, a robot, a portable electronic device, a wireless device, or the like. The network 128 may include the Internet, a wide area network (“WAN”), a metropolitan area network (“MAN”), a local area network (“LAN”), a token ring, a wireless network, a fiber channel network, a SAN, network attached storage (“NAS”), ESCON, or the like, or any combination of networks. The network 128 may also include a network from the IEEE 802 family of network technologies, such Ethernet, token ring, WiFi, WiMax, and the like.

The network 128 may include servers, switches, routers, cabling, radios, and other equipment used to facilitate networking the host 108 or hosts and host 126 or clients. In one embodiment, the storage system 100 includes multiple hosts that communicate as peers over a network 128. In another embodiment, the storage system 100 includes multiple memory devices 102 that communicate as peers over a network 128. One of skill in the art will recognize other computer networks comprising one or more computer networks and related equipment with single or redundant connection between one or more clients or other computer with one or more memory devices 102 or one or more memory devices 102 connected to one or more hosts. In one embodiment, the storage system 100 includes two or more memory devices 102 connected through the network 128 to a host 126 without a host 108.

In one embodiment, the storage client 112 communicates with the storage controller 104 through a host interface comprising an Input/Output (I/O) interface. For example, the storage device 102 may support the ATA interface standard, the ATA Packet Interface (“ATAPI”) standard, the small computer system interface (“SCSI”) standard, and/or the Fibre Channel standard which are maintained by the InterNational Committee for Information Technology Standards (“INCITS”).

In certain embodiments, the storage media of a memory device is divided into volumes or partitions. Each volume or partition may include a plurality of sectors. Traditionally, a sector is 512 bytes of data. One or more sectors are organized into a block (referred to herein as both block and data block, interchangeably).

In one example embodiment, a data block includes eight sectors which is 4 KB. In certain storage systems, such as those interfacing with the Windows® operating systems, the data blocks are referred to as clusters. In other storage systems, such as those interfacing with UNIX, Linux, or similar operating systems, the data blocks are referred to simply as blocks. A block or data block or cluster represents a smallest physical amount of storage space on the storage media that is managed by a storage manager, such as a storage controller, storage system, storage unit, storage device, or the like.

In some embodiments, the storage controller 104 may be configured to store data on one or more asymmetric, write-once storage media, such as solid-state storage memory cells within the memory die 106. As used herein, a “write once” storage media refers to storage media that is reinitialized (e.g., erased) each time new data is written or programmed thereon. As used herein, an “asymmetric” storage media refers to a storage media having different latencies for different storage operations. Many types of solid-state storage media (e.g., memory die) are asymmetric; for example, a read operation may be much faster than a write/program operation, and a write/program operation may be much faster than an erase operation (e.g., reading the storage media may be hundreds of times faster than erasing, and tens of times faster than programming the storage media).

The memory die 106 may be partitioned into memory divisions that can be erased as a group (e.g., erase blocks) in order to, inter alia, account for the asymmetric properties of the memory die 106 or the like. “Erase block” refers to a logical erase block or a physical erase block. In one embodiment, a physical erase block represents the smallest storage unit within a given memory die that can be erased at a given time (e.g., due to the wiring of storage cells on the memory die). In one embodiment, logical erase blocks represent the smallest storage unit, or storage block, erasable by a storage controller in response to receiving an erase command. In such an embodiment, when the storage controller receives an erase command specifying a particular logical erase block, the storage controller may erase each physical erase block within the logical erase block simultaneously. It is noted that physical erase blocks within a given logical erase block may be considered as contiguous within a physical address space even though they reside in separate dies. Thus, the term “contiguous” may be applicable not only to data stored within the same physical medium, but also to data stored within separate media.

As such, modifying a single data segment in-place may require erasing the entire erase block comprising the data, and rewriting the modified data to the erase block, along with the original, unchanged data. This may result in inefficient write amplification, which may excessively wear the memory die 106. “Write amplification” refers to a measure of write/programming operations performed on a non-volatile storage device which result in writing any data, and user data in particular, more times than initially writing the data in a first instance. in certain embodiments, write amplification may count the number of write operations performed by a non-volatile storage device in order to manage and maintain the data stored on the non-volatile storage device. in other embodiments, write amplification measures the amount of data, the number of bits, written that are written beyond an initial storing of data on the non-volatile storage device.

Therefore, in some embodiments, the storage controller 104 may be configured to write data out-of-place. As used herein, writing data “out-of-place” refers to writing data to different media storage location(s) rather than overwriting the data “in-place” (e.g., overwriting the original physical location of the data). Modifying data out-of-place may avoid write amplification, since existing, valid data on the erase block with the data to be modified need not be erased and recopied. Moreover, writing data out-of-place may remove erasure from the latency path of many storage operations (e.g., the erasure latency is no longer part of the critical path of a write operation).

Management of a data block by a storage manager includes specifically addressing a particular data block for a read operation, write operation, or maintenance operation. A block storage device may associate n blocks available for user data storage across the storage media with a logical address, numbered from 0 to n. In certain block storage devices, the logical addresses may range from 0 to n per volume or partition.

In conventional block storage devices, a logical address maps directly to a particular data block on physical storage media. In conventional block storage devices, each data block maps to a particular set of physical sectors on the physical storage media. However, certain storage devices do not directly or necessarily associate logical addresses with particular physical data blocks. These storage devices may emulate a conventional block storage interface to maintain compatibility with a block storage client 112.

In one embodiment, the storage controller 104 provides a block I/O emulation layer, which serves as a block device interface, or API. In this embodiment, the storage client 112 communicates with the storage device through this block device interface. In one embodiment, the block I/O emulation layer receives commands and logical addresses from the storage client 112 in accordance with this block device interface. As a result, the block I/O emulation layer provides the storage device compatibility with a block storage client 112.

In one embodiment, a storage client 112 communicates with the storage controller 104 through a host interface comprising a direct interface. In this embodiment, the storage device directly exchanges information specific to non-volatile storage devices. “Non-volatile storage device” refers to any hardware, device, component, element, or circuit configured to maintain an alterable physical characteristic used to represent a binary value of zero or one after a primary power source is removed. Examples of a non-volatile storage device include, but are not limited to, a hard disk drive (HDD), Solid-State Drive (SSD), non-volatile memory media, and the like.

A storage device using direct interface may store data in the memory die 106 using a variety of organizational constructs including, but not limited to, blocks, sectors, pages, logical blocks, logical pages, erase blocks, logical erase blocks, ECC codewords, logical ECC codewords, or in any other format or structure advantageous to the technical characteristics of the memory die 106.

The storage controller 104 receives a logical address and a command from the storage client 112 and performs the corresponding operation in relation to the memory die 106. The storage controller 104 may support block I/O emulation, a direct interface, or both.

FIG. 2 is a block diagram of an exemplary storage device 102. The storage device 102 may include a storage controller 104 and a memory array 202. Each memory die 106 in the memory array 202 may include a die controller 204 and at least one non-volatile memory array 206 in the form of a three-dimensional array, and read/write circuits 208.

“Memory array” refers to a set of storage cells (also referred to as memory cells) organized into an array structure having rows and columns. A memory array is addressable using a row identifier and a column identifier. Consequently, a non-volatile memory array is a memory array having memory cells configured such that a characteristic (e.g., threshold voltage level, resistance level, conductivity, etc.) of the memory cell used to represent stored data remains a property of the memory cell without a requirement for using a power source to maintain the characteristic. “Characteristic” refers to any property, trait, quality, or attribute of an object or thing. Examples of characteristics include, but are not limited to, condition, readiness for use, unreadiness for use, chemical composition, water content, temperature, relative humidity, particulate count, a data value, contaminant count, and the like.

A memory array is addressable using a row identifier and a column identifier. Those of skill in the art recognize that a memory array may comprise the set of memory cells within a plane, the set of memory cells within a memory die, the set of memory cells within a set of planes, the set of memory cells within a set of memory die, the set of memory cells within a memory package, the set of memory cells within a set of memory packages, or with other known memory cell set architectures and configurations.

A memory array may include a set of memory cells at a number of levels of organization within a storage or memory system. In one embodiment, memory cells within a plane may be organized into a memory array. In one embodiment, memory cells within a plurality of planes of a memory die may be organized into a memory array. In one embodiment, memory cells within a plurality of memory dies of a memory device may be organized into a memory array. In one embodiment, memory cells within a plurality of memory devices of a storage system may be organized into a memory array.

The non-volatile memory array 206 is addressable by word line via a row decoder 210 and by bit line via a column decoder 212. “Word line” refers to a structure within a memory array comprising a set of memory cells. The memory array is configured such that the operational memory cells of the word line are read or sensed during a read operation. Similarly, the memory array is configured such that the operational memory cells of the word line are read, or sensed, during a read operation.

The read/write circuits 208 include multiple sense blocks SB1, SB2, . . . , SBp (sensing circuitry) and allow a page of memory cells to be read or programmed in parallel. In certain embodiments, each memory cell across a row of the memory array together form a physical page.

A physical page may include memory cells along a row of the memory array for a single plane or for a single memory die. In one embodiment, the memory die includes a memory array made up of two equal sized planes. In one embodiment, a physical page of one plane of a memory die includes four data blocks (e.g., 16 KB). In one embodiment, a physical page (also called a “Die page”) of a memory die includes two planes each having four data blocks (e.g., 32 KB).

Commands and data are transferred between the host 108 and storage controller 104 via a data bus 122, and between the storage controller 104 and the one or more memory die 106 via bus 124. The storage controller 104 may comprise the logical modules described in more detail with respect to FIG. 1.

The non-volatile memory array 206 can be two-dimensional (2D—laid out in a single fabrication plane) or three-dimensional (3D—laid out in multiple fabrication planes). The non-volatile memory array 206 may comprise one or more arrays of memory cells including a 3D array. In one embodiment, the non-volatile memory array 206 may comprise a monolithic three-dimensional memory structure (3D array) in which multiple memory levels are formed above (and not in) a single substrate, such as a wafer, with no intervening substrates. The non-volatile memory array 206 may comprise any type of non-volatile memory that is monolithically formed in one or more physical levels of arrays of memory cells having an active area disposed above a silicon substrate. The non-volatile memory array 206 may be in a non-volatile solid-state drive having circuitry associated with the operation of the memory cells, whether the associated circuitry is above or within the substrate.

“Circuitry” refers to electrical circuitry having at least one discrete electrical circuit, electrical circuitry having at least one integrated circuit, electrical circuitry having at least one application specific integrated circuit, circuitry forming a general purpose computing device configured by a computer program (e.g., a general purpose computer configured by a computer program which at least partially carries out processes or devices described herein, or a microprocessor configured by a computer program which at least partially carries out processes or devices described herein), circuitry forming a memory device (e.g., forms of random access memory), or circuitry forming a communications device (e.g., a modem, communications switch, or optical-electrical equipment). Word lines may comprise sections of the layers containing memory cells, disposed in layers above the substrate. Multiple word lines may be formed on single layer by means of trenches or other non-conductive isolating features.

The die controller 204 cooperates with the read/write circuits 208 to perform memory operations on memory cells of the non-volatile memory array 206, and includes a state machine 214, an address decoder 216, and a power control 218. The state machine 214 provides chip-level control of memory operations.

The address decoder 216 provides an address interface between that used by the host or a storage controller 104 to the hardware address used by the row decoder 210 and column decoder 212. The power control 218 controls the power and voltages supplied to the various control lines during memory operations. The power control 218 and/or read/write circuits 208 can include drivers for word lines, source gate select (SGS) transistors, drain gate select (DGS) transistors, bit lines, substrates (in 2D memory structures), charge pumps, and source lines. In certain embodiments, the power control 218 may detect a sudden loss of power and take precautionary actions. The power control 218 may include various first voltage generators (e.g., the drivers) to generate the voltages described herein. The sense blocks can include bit line drivers and sense amplifiers in one approach.

In some implementations, some of the components can be combined. In various designs, one or more of the components (alone or in combination), other than non-volatile memory array 206, can be thought of as at least one control circuit or storage controller which is configured to perform the techniques described herein. For example, a control circuit may include any one of, or a combination of, die controller 204, state machine 214, address decoder 216, column decoder 212, power control 218, sense blocks SB1, SB2, . . . , SBp, read/write circuits 208, storage controller 104, and so forth.

In one embodiment, the host 108 is a computing device (e.g., laptop, desktop, smartphone, tablet, digital camera) that includes one or more processors, one or more processor readable storage devices (RAM, ROM, flash memory, hard disk drive, solid state memory) that store processor readable code (e.g., software) for programming the storage controller 104 to perform the methods described herein. The host may also include additional system memory, one or more input/output interfaces and/or one or more input/output devices in communication with the one or more processors, as well as other components well known in the art.

Associated circuitry is typically required for operation of the memory cells and for communication with the memory cells. As non-limiting examples, memory devices may have circuitry used for controlling and driving memory cells to accomplish functions such as programming and reading. This associated circuitry may be on the same substrate as the memory cells and/or on a separate substrate. For example, a storage controller for memory read-write operations may be located on a separate storage controller chip and/or on the same substrate as the memory cells.

One of skill in the art will recognize that the disclosed techniques and devices are not limited to the two-dimensional and three-dimensional exemplary structures described but covers all relevant memory structures within the spirit and scope of the technology as described herein and as understood by one of skill in the art.

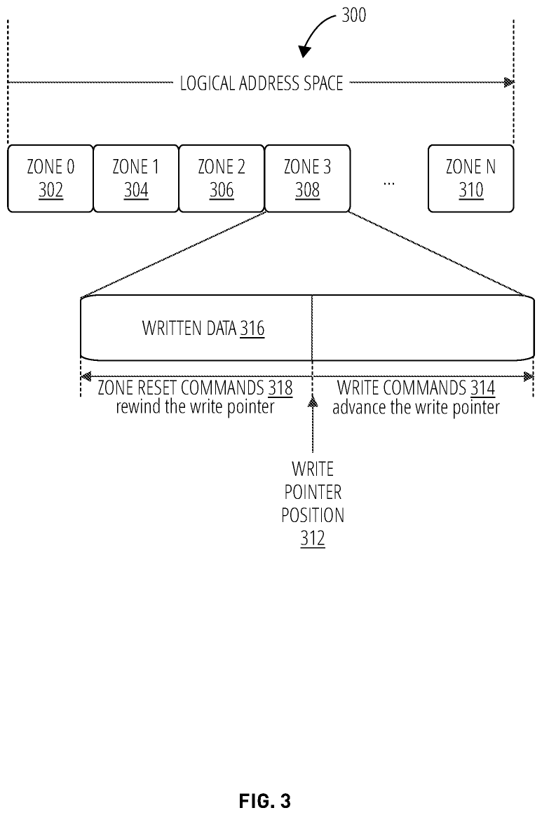

FIG. 3 illustrates a logical address space with zoned storage allocation 300 in accordance with one embodiment. The logical address space with zoned storage allocation 300 may comprise a zone 0 302, zone 1 304, zone 2 306, zone 3 308, etc., up to a final zone N 310. “Logical address space” refers to a logical representation of memory resources. The logical address space may comprise a plurality (e.g., range) of logical addresses.

The zoned storage device standard requires that zones be written sequentially. Each zone of the device address space has a write pointer 312 that keeps track of the position of the next write. Write commands 314 will advance the write pointer 312 to the end of the newly written data 316. “Write command” refers to a storage command configured to direct the recipient to write, or store, one or more data blocks on a persistent storage media, such as a hard disk drive, non-volatile memory media, or the like. A write command may include any storage command that may result in data being written to physical storage media of a storage device. The write command may include enough data to fill one or more data blocks, or the write command may include enough data to fill a portion of one or more data blocks. In one embodiment, a write command includes a starting LBA and a count indicating the number of LBA of data to write to on the storage media. Written data 316 in a zone cannot be directly overwritten. To overwrite data or reuse programmed non-volatile memory media, the zone must first be erased using a zone reset command 318 that rewinds the write pointer 312 to the start of the zone.

Zoned storage devices can be implemented using various recording and media technologies. The most common form of zoned storage today uses the SCSI Zoned block Commands (ZBC) and Zoned ATA Commands (ZAC) interfaces on Shingled Magnetic Recording (SMR) HDDs. ZBC and ZAC enable a zoned block storage model; SMR technology enables continued areal density growth to meet the demands for expanding data needs and requires the zoned block access model.

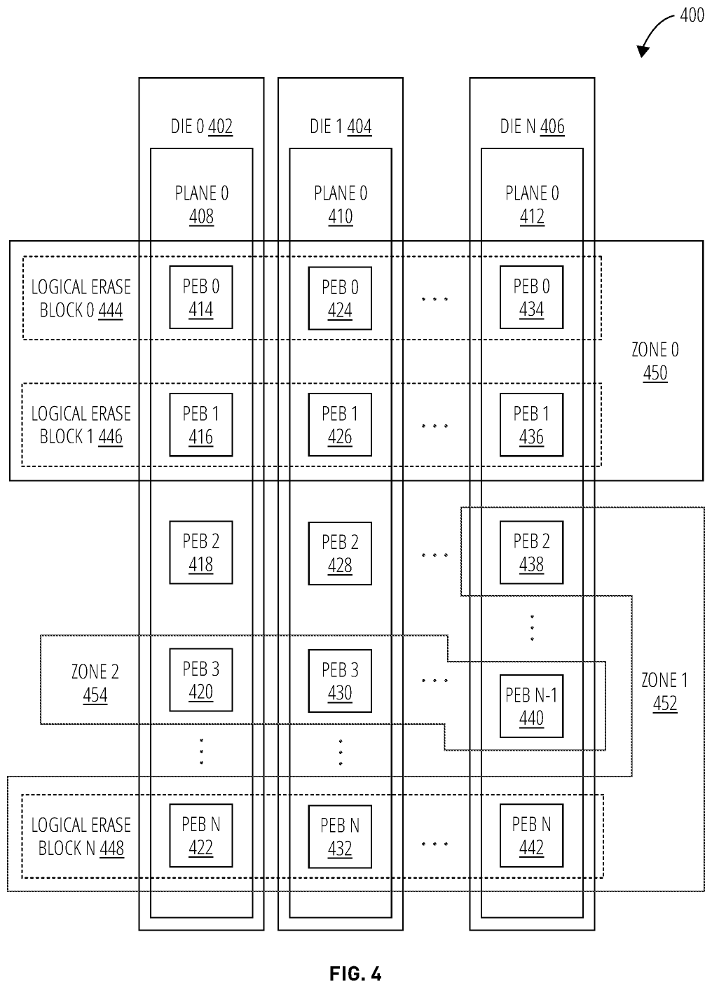

FIG. 4 illustrates a ZNS storage device 400 in accordance with one embodiment. The ZNS storage device 400 comprises a plurality of dies: die 0 402, die 1 404, etc., through die n 406. Each illustrated die is shown with a single plane (plane 0 408, plane 0 410, and plane 0 412 respectively). In some embodiments, each die may include a second plane 1, which is not illustrated. “Plane” refers to a division of the memory array that permits certain storage operations to be performed on both planes using certain physical row addresses and certain physical column addresses.

Multiple physical erase blocks (PEBs) per plane per die may be used in the ZNS storage device 400, such as the illustrated physical erase block 0 414, physical erase block 1 416, physical erase block 2 418, physical erase block 3 420, physical erase block n 422, physical erase block 0 424, physical erase block 1 426, physical erase block 2 428, physical erase block 3 430, physical erase block n 432, physical erase block 0 434, physical erase block 1 436, physical erase block 2 438, physical erase block n-1 440, and physical erase block n 442. “Physical erase block” refers to smallest storage unit within a given memory die that can be erased at a given time (e.g., due to the wiring of storage cells on the memory die).

In the illustrated embodiment, ZNS storage device 400 may be organized into logical erase blocks (LEBs), as shown by logical erase block 0 444, logical erase block 1 446, and logical erase block N 448. Those of skill in the art appreciate the relationship and differences between physical erase block and a logical erase block and may refer to one, or the other, or both by using the shorthand versions “erase block” or “block.” Those of skill in the art understand from the context of the reference to an erase block whether a physical erase block or a logical erase block is being referred to. The concepts and techniques used in the art and those recited in the claims can be equally applied to either physical erase blocks or logical erase blocks.

Under the zoned storage device standard, the logical construct of a “zone” is used to group logical erase blocks or physical erase blocks for the purpose of reducing device-side write amplification and reducing overprovisioning by aligning host write patterns with internal device geometry and reducing the need for device-side writes which are not directly linked to a host write.

In some embodiments, a zone may be constructed based on the architecture of the ZNS storage device 400. For example, pairs of logical erase blocks may be grouped into a zone, such as the zone 0 450 illustrated, which comprises logical erase block 0 444 and logical erase block 1 446. In other embodiments, zone grouping may be adjusted based on zone metrics, as disclosed herein.

In one embodiment, individual physical erase blocks may be assigned to any zone, regardless of their location within the ZNS storage device 400 or assignment to a logical erase block. Examples of such zones may be seen in zone 1 452 and zone 2 454.

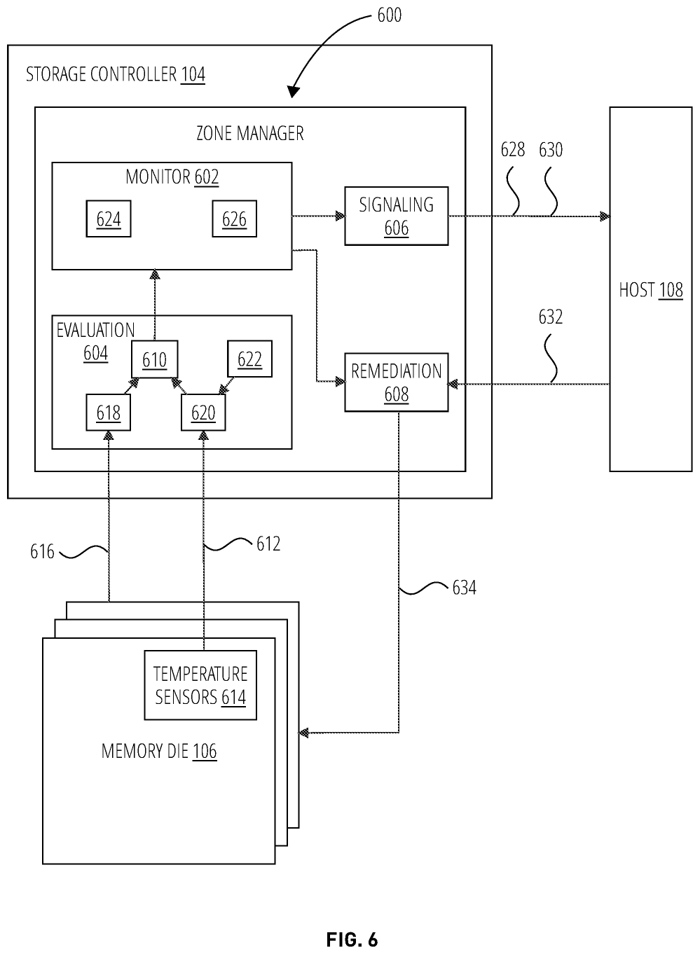

In embodiments where zone assignments are not confined to predetermined physical and logical structures within the ZNS storage device 400, a zone mapping structure may be maintained within a storage controller, similar to an address mapping table or LBA lookup table. Such a zone lookup table may be maintained within the zone manager 600, discussed in more detail with regard to FIG. 6.

In another embodiment, a zone comprises one physical erase block per plane per die. One example of such a physical erase block allocation to a zone is zone 0 450. In such an embodiment, if one physical erase block becomes unusable or inoperative, that physical erase block may be removed from the zone allocation, then next time the zone is erased and re-opened. In such an embodiment, the physical size of the zone may change because of removed unhealthy or inoperative physical erase blocks.

In some embodiments, a die controller and/or storage controller may associate metadata with one or more of the storage blocks (logical erase blocks, physical erase blocks, zones). “Metadata” refers to system data usable to facilitate operation of non-volatile storage device. Metadata stands in contrast to, for example, data produced by an application (i.e., “application data”) or forms of data that would be considered by an operating system as “user data.”

For example, a zone or a logical erase block may include metadata specifying, without limitation, usage statistics (e.g., the number of program erase cycles performed on that zone or logical erase block, health statistics (e.g., a value indicative of how often corrupted data has been read from that zone or logical erase block), security or access control parameters, sequence information (e.g., a sequence indicator), a persistent metadata flag (e.g., indicating inclusion in an atomic storage operation), a transaction identifier, or the like. In some embodiments, zone or logical erase block includes metadata identifying the logical addresses for which the zone or logical erase block stores data, as well as the respective numbers of stored data blocks/packets for each logical block or sector within a zone.

In certain embodiments, the metadata comprises a cross temperature for a zone, an average cross temperature for open zones of the non-volatile storage device, a temperature change rate, an average program erase count for a zone, an uncorrectable bit error rate (UBER) for a zone, a fail bit count for a zone, and a charge leak rate. “Uncorrectable bit error rate” refers to a measure of a rate indicating a number of bits that are that are uncorrectable and in error for a given number of bits that are processed. Bits that are uncorrectable are deemed uncorrectable after one or more error correction techniques are attempted such as use of Error Correction Codes (ECC), use of Bose, Chaudhuri, Hocquenghem (BCH) codes, use of a Low Density Parity Check (LDPC) algorithm, and the like. “Fail bit count” refers to a measure of a number of bits that are in error for a given unit of measure. Bits that are in error are bits that were stored with one value but then when the same bits where read or sensed the bit indicated a different value. Fail bit counts may be measured for data block (e.g., 4K), an erase block, a page, a logical erase block, a zone, a namespace, or the like. Said another way, the failed bit count may be a number of bits that differ between data written to a data block, physical erase block, or other grouping of memory cells and data subsequently read from data block, physical erase block, or other grouping of memory cells. “Charge leak rate” refers to a rate at which current leaks from a memory cell when the memory cell is in a passive state, not being read or written to.

A logical address space represents the organization of data as perceived by higher-level processes such as applications and operating systems. In one embodiment, a physical address space represents the organization of data on the physical media.

In one embodiment, the metadata may be provided in a message with data resulting from a read command or in response to command from the storage client. Data packets from the storage device may include packet metadata such as one or more LBAs associated with the contained data, the packet size, linkages to other packets, error correction checksums, etc.

In various embodiments, a storage client such as a device driver may use this information, along with other forms of metadata, to manage operation of ZNS storage device 400. For example, the device driver may use this metadata to facilitate performance of read and write operations, recover the ZNS storage device 400 to a previous state (including, for example, reconstruction of various data structures used by device driver and/or replaying a sequence of storage operations performed on ZNS storage device 400), etc. Various forms of this metadata may be used.

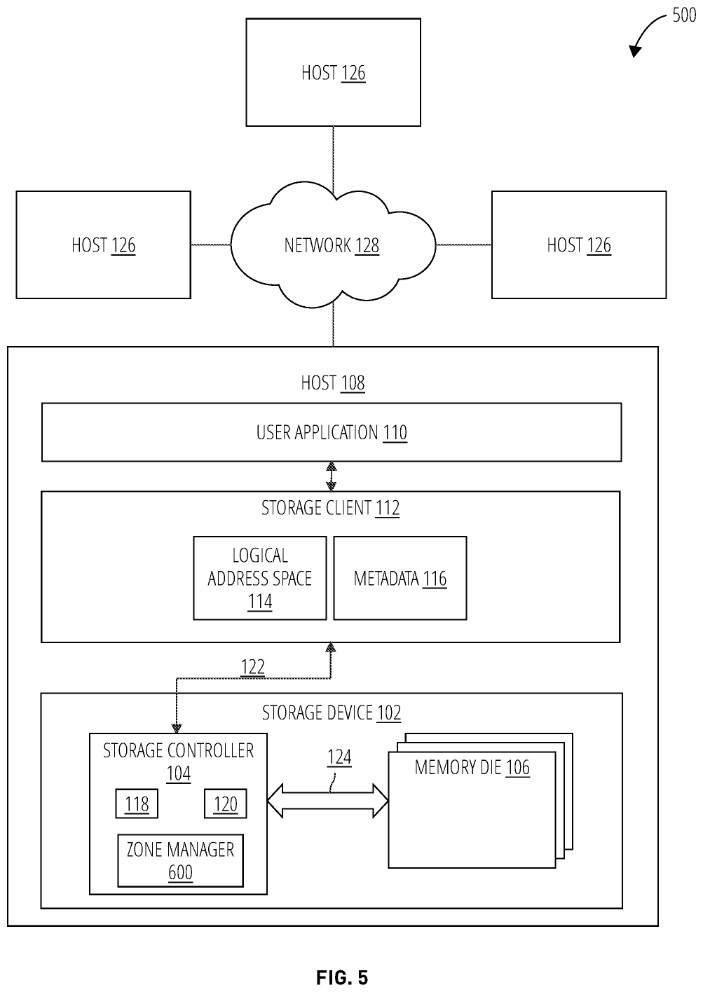

FIG. 5 is a schematic block diagram illustrating one embodiment of a ZNS storage system 500 in accordance with the disclosed solution. The ZNS storage system 500 may comprise similar functional components in the similar arrangements as presented in FIG. 1. FIG. 1 and FIG. 5 illustrate that certain features, functions, and logic are implemented by one or more storage clients 112. For example, in the embodiments of FIG. 1 and FIG. 5, storage client 112 includes logical address space 114, metadata 116, FLASH translation layer 118, and address mapping table 120. Placement of these components in one or more storage clients 112, such as a device driver, an operating system, a database, a file system, or the like, gives the host more control over how data is organized, laid out, and managed on the storage device 102.

While the configuration of the ZNS storage system 500 gives the host more control, in a host implementing a zoned storage device standard, the host 108 may not make the most optimal use of the non-volatile memory media under the current zoned storage device standard. For example, the host may have no information, or not specific enough information about the physical health and condition of the non-volatile memory media. In particular, the host 108 may have limited, or no information, about a health of non-volatile memory media used in a particular zone, or in each zone. Furthermore, the host 108 may have limited, or no information, about a non-volatile memory media that is subject to a cross temperature phenomena.

Certain embodiments of the claimed solution address, at least, this missing aspect of the zoned storage device standard by incorporating a zone manager 600 into the storage controller 104. The zone manager may monitor and manage specific physical characteristics and attributes of physical erase blocks that make up the zone. In one embodiment, the zone manager 600 manages one or more zone metrics.

“Zone metric” refers to a measure of the status, condition, functionality, reliability, and/or viability of a zone. A zone metric may be associated with any scale or unit of measure that conveys at a suitable level of granularity the status, condition, functionality, reliability, and/or viability of the zone. For example, in one embodiment, the zone metric is associated with a scale of whole numbers between 1 and 10 in which a 1 on the scale represents an optimal and properly functioning zone and a 10 on the scale represents a poor and unreliable zone.

In one embodiment, the zone metric is a measure of the condition of a zone based on one or more metrics for the physical erase blocks that make up the zone. In a particular embodiment, the zone metric comprises a block health metric. In another embodiment, the zone metric comprises a cross temperature metric. In another embodiment, the zone metric is a measure that combines a block health metric and a cross temperature metric. In certain embodiments, a zone metric may also be referred to as zone block metric, at least in part, because of a relationship between the zone metric and physical erase blocks that may form the zone.

Examples of one or more metrics for the physical erase blocks that make up the zone that may be used to determine the zone metric, include, but are not limited to a PE cycle count for one or more of the physical erase block that make up the zone, a physical position of the physical erase blocks in a non-volatile memory array relative to other components, a read frequency of data from certain physical erase blocks that make up the zone. “PE cycle” refers to a count of the number of times a set of memory cells is programmed and erased. The set of memory cells may include any collection of memory cell including a data block, a word line, a page, a logical page, an erase block, a logical erase block, a memory array, a memory die, or the like. PE cycles may be designated in units of thousands, such as 4k, 50k, and the like.

In certain embodiments, a zone manager 600 may manage a plurality of zone metrics. Two examples of a zone metric include a block health metric and cross temperature metric. “Block health metric” refers to a health metric for one or more physical erase blocks. In one embodiment, a block health metric is a health metric for a single physical erase block. In another embodiment, a block health metric is a health metric for a set of physical erase blocks, such as for example, the physical erase blocks that make up a zone.

“Health metric” refers to any measurable quantity, or aspect, indicative of the health, or reliability, of a set of memory cells. As memory cells are used, they become worn such that read and write operations may take more time, for example due to additional error detection and correction required. Examples of characteristics that may be used to determine a health metric may include program erase cycle counts (PE counts), likelihood of successfully obtaining data stored in memory cells, remaining useful life, a wear level, an error rate, fail bit count, rate of change in health and/or reliability, and/or the like.

“Cross temperature metric” refers to a measure of a cross temperature condition. In one embodiment, the cross-temperature metric comprises a difference between a temperature when a memory cell is programmed/written and a temperature when a memory cell is read or attempted to be read.

The zone manager 600 may use one or more zone metrics to determine a zone health. The zone manager 600 coordinates with the storage controller 104 to communicate the zone health back to the one or more storage clients 112 managing and using the storage device 102 within the ZNS storage system 500. Communicating this zone health to the host, and/or to one or more storage clients 112 of the host, enables the host to make informed management decisions regarding data on zones of the storage device 102. For example, high priority, high value, data may be stored on zones with a maximum zone health. Less important data, or data that is accessed less frequently, may be stored on zones with a reduced zone health.

Furthermore, with zone health information from the zone manager 600, the host may determine which zones to close, when to open a new zone, when to relocate data from a first zone to a second zone, and other non-volatile memory media management decisions. In this manner, the zone health provided by the zone manager 600 to the host improves the management of data in the ZNS storage system 500 and thereby improves the ZNS storage system 500.

In addition to tracking, determining, and communicating zone metrics, the zone manager 600 may also receive and respond to zone management commands from the host 108 (and/or storage clients 112). Zone management commands include, for example, zone write lock, open zone, zone close, reset zone, zone report, and the like. The zone manager 600 may communicate a zone metric and/or a zone health using a variety of techniques. In one embodiment, the zoned storage device standard may be changed to include a zone metric as part of a zone status reported by the storage device 102 in response to a host request for a zone information log. In another embodiment, a storage device 102 may interrupt the host 108 to provide the zone metric. These techniques and others known to those of skill in the art are within the scope of the solution claimed herein.

In one embodiment, the zone manager 600 may signal the storage controller 104 to report a zone metric and/or zone health back to the host 108. The host 108 may then determine what, if any, countermeasures may be necessary based on the reported zone health and/or zone metric. In embodiments, where the zone manager 600 proactively notifies the host 108 the countermeasures can improve the state and quality of storage services provided by the storage device 102. The host 108 may direct the storage device 102 to implement a countermeasure by way of a countermeasure command.

“Countermeasure” refers to a method, process, step or operation configured to mitigate a negative attribute, factor, or condition. It should be noted that in certain instances a viable countermeasure is to take no action with respect to an identified negative attribute, factor, or condition. While taking no action may be considered a passive activity, such a response to a negative attribute, factor, or condition is considered a countermeasure herein.

In certain embodiments, a countermeasure is specific to a particular problem or indication of a problem. Examples of countermeasures, that may be used include closing a zone, actively changing a temperature of erase blocks within a zone, relocating data of a zone to another zone, adjusting an alert threshold, managing one or more physical erase blocks of a zone using separate Cell Voltage Distribution (CVD) tables, and taking no action.

“Cell Voltage Distribution (CVD) table” refers to a data structure such as a look up table that stores read voltage threshold values for a given set of memory cells for each of a number of states that are managed for the memory cells. In one embodiment, where memory cells store one bit (Single Level Cell—SLC) a CVD table may store read threshold value settings (or offsets) for each of two states. In an embodiment, where memory cells store two bits (Multi-Level Cell—MLC) a CVD table may store read threshold value settings (or offsets) for each of four states. In an embodiment, where memory cells store three bits (Multi-Level Cell—MLC) a CVD table may store read threshold value settings (or offsets) for each of eight states.

In certain embodiments, each physical erase block is associated with a CVD table. Alternatively, or in addition, a CVD table may include read threshold value settings (or offsets) based on a range of PE cycles and/or range of temperatures. By using a CVD table of read threshold voltages that varies depending on the physical erase block being read and/or the PE cycle for the physical erase block and/or the temperature, a die controller or storage controller may accurately read data form the physical erase block in a reliable manner.

Examples of countermeasures are included herein. Those of skill in the art will recognize a variety of countermeasures that the host 108 may use. In certain instances, the host 108 may determine that the appropriate response to the reported zone metric may be to take no action. In certain embodiments, taking no action may comprise a countermeasure.

In certain embodiments, zone health may be a subjective, or relative measure, based on a scale or range and based on a number of factors and parameters combined using logic, circuitry, firmware, software, or the like. In another embodiment, zone health may be indicated solely by a zone metric which may comprise an objective measure such as a number or value calculated based on zone health, health metrics, or other parameters.

FIG. 6 illustrates a zone manager 600 in accordance with one embodiment. The zone manager 600 may be configured to manage storage allocation and storage operations under a Zoned Namespaces (ZNS) implementation in accordance with the zoned storage device standard. The zone manager 600 may comprise a monitor circuit 602, an evaluation circuit 604, a signaling circuit 606, and a remediation circuit 608. The zone manager 600 may be implemented within the storage controller 104 of a memory device as illustrated in FIG. 5. Alternatively, or in addition, the zone manager 600 may comprise a component separate from the storage controller 104.

The evaluation circuit 604 may be configured to determine a zone health for each zone with regard to a zone metric 610. Alternatively, or in addition, the zone manager 600 may determine a zone health for a set of zones, such as a set of open zones, with regard to a zone metric 610 for each zone and/or an aggregate zone metric for the set of zones. In one embodiment, the zone metric 610 comprises a block health metric 618 for each zone. In another embodiment, the zone metric 610 comprises a cross temperature metric 620 for each zone.

“Zone health” refers to a measure of an overall condition of a zone. In certain embodiments, the zone health indicates a level of reliability and/or stability of the zone. In one embodiment, zone health comprises a combination of a block health metric, a cross temperature metric, and a variety of other factors, including, but not limited to, an average PE cycle for physical erase blocks that make up a zone, a read rate, a fail bit count for the zone, a number of inoperable physical erase blocks that may be a part of a zone, and the like. In certain embodiments, a zone health may be determined based on a formula that factors in the variety of factors just listed. In another embodiment, a zone health may be based on statistical data, statistical formulas and/or predictive measures based on heuristic data collected by a manufacturer of memory cells.

The zone health is a measure for a zone which may comprise a plurality of physical erase blocks. In one embodiment, the zone health is representative of a least healthy physical erase block of those that make up the zone (e.g., a more conservative zone health measure). In another embodiment, the zone health is representative of a most healthy physical erase block of those that make up the zone. In another embodiment, the zone health is representative of an aggregate health, such as an average health, of physical erase blocks of those that make up the zone.

The evaluation circuit 604 may, for example, receive temperature readings 612 from one or more temperature sensors 614 configured to monitor multiple physical erase blocks in each zone. The temperature readings 612 may comprise a temperature for a die, a plane, a physical erase block, and/or for the memory device. The evaluation circuit 604 may receive temperature readings 612 on a periodic basis (e.g., every 60 seconds) or in response to an event such as a programming storage operation. In addition, the evaluation circuit 604 may access metadata indicating a temperature when data of a physical erase block or zone was written to (e.g., a programmed temperature), for example in response to a read storage operation on data of the zone.

“Temperature sensor” refers to any suitable technology that can implement a temperature sensor, including technology currently employed in conventional memory temperature sensors. Also, it should be noted that while the temperature sensor may be located in the memory die in this embodiment, the temperature sensor may be located in another component in the storage system, such as the controller, or can be a separate component in the storage system.

The evaluation circuit 604 may determine a cross temperature metric 620 based on the temperature readings 612 and a programmed temperature 622. “Programmed temperature” refers to the temperature of the memory cells and/or memory die at the time that data is programmed (i.e., stored) to the memory cells. In certain embodiments, the programmed temperature 622 may be stored in a header for a physical erase block and the evaluation circuit 604 may retrieve the programmed temperature 622 from volatile memory or from the non-volatile memory media. Alternatively, the programmed temperature 622 may be stored in a table for comparison with measured temperature readings 612.

In certain embodiments, to determine the zone health, the evaluation circuit 604 may review and take into account a variety of factors and considerations with respect to the physical erase blocks of a zone. In one embodiment, the evaluation circuit 604 may be configured to determine wear levels for each physical erase block of each zone based on wear level data 616.

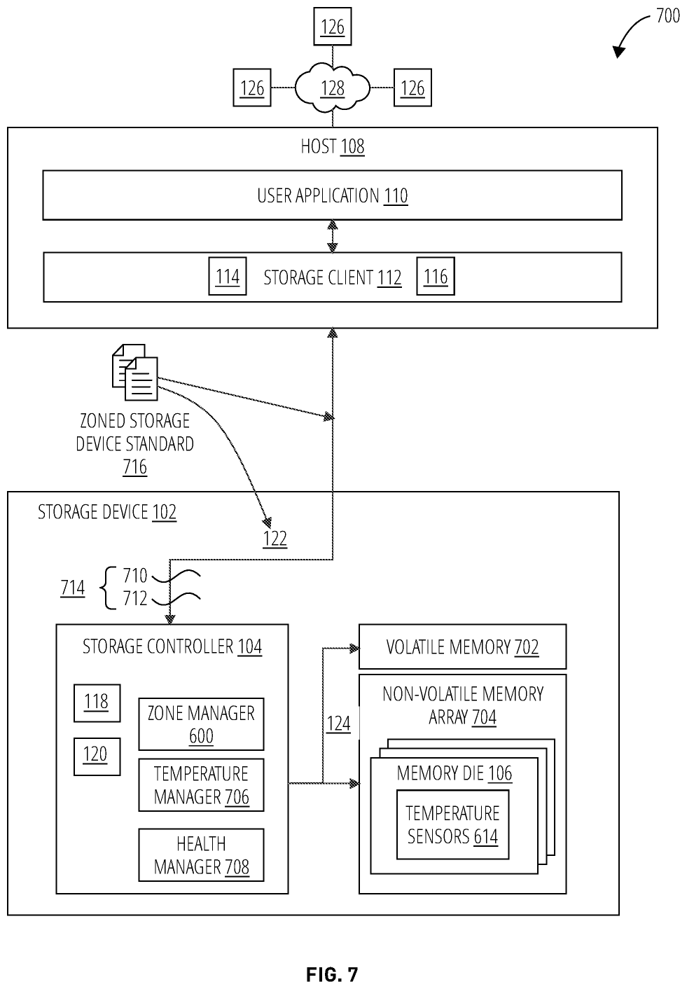

The wear level data 616 may be determined dynamically as needed and may include static data reflecting the use patterns and condition of the physical erase blocks of a zone. In one embodiment, the wear level data 616 may be provided by monitoring the physical memory die 106, or on other control and management circuitry. The evaluation circuit 604 may determine a block health metric 618 based on a wear level for the physical erase block. In one embodiment, the evaluation circuit 604 may determine a zone metric 610 based on the cross-temperature metric 620. In one embodiment, the evaluation circuit 604 determines a zone metric 610 based on the block health metric 618 and/or the cross-temperature metric 620. In some embodiments, the wear level data 616 and temperature readings 612 may be provided by a system such as that illustrated in FIG. 7.

“Wear level” refers to a measure of a condition of a set of memory cells to perform their designed function of storing, retaining, and providing data. In certain embodiments, wear level is a measure of the amount of deterioration a set of memory cell has experienced. Wear level may be expressed in the form of a certain number of PE cycles relative to total number of PE cycles the memory cells are expected to complete before becoming defective/inoperable.

For example, suppose a set of memory cells are designed and fabricated to suitably function for five thousand PE cycles. Once the example set of memory cells reaches two thousand PE cycles, the wear level may be expressed as a ratio of the number of PE cycles completed to the number of PE cycles the set is designed to complete. In this example, the wear level may be expressed as 2/5, 0.4, or 40% worn, or used. The wear level may also be expressed in terms of how many PE cycles are expected from the set. In this example, the remaining wear, or life, of the set of memory cells may be 3/5, 0.6, or 60%. Said another way, wear level may represent the amount of wear, or life, of a memory cell that has been used or wear level may represent the amount of wear, or life, of a memory cell that remains before the memory cell is defective, inoperable, or unusable.

The monitor circuit 602 tracks a plurality of zone metrics 610. In one embodiment, the monitor circuit 602 may be configured to monitor the zone metric 610 for each zone of a non-volatile storage device. The monitor circuit 602 may include an alert threshold 624 used to determine when a zone metric 610 for a particular zone or set of zone is at or outside a specific level. In one embodiment, the monitor circuit 602 tracks groups of zones in relation to a particular alert threshold 624. For example, the monitor circuit 602 may track all open zones against a particular alert threshold 624.

The monitor circuit 602 may be further configured with a critical threshold 626 against which the zone metric 610 may be monitored. The alert threshold 624 and critical threshold 626 may in alternative embodiments be configured as part of the evaluation circuit 604, other logic within the storage controller 104, or logic within the host 108. In one embodiment, when a critical threshold 626 is satisfied the alert threshold 624 is also satisfied.

“Critical threshold” refers to a type of threshold that is predefined such that when a value, rating or condition satisfies the critical threshold, the system, apparatus, or method is configured to raise a higher signal of either a problem or error or a potential for an imminent problem or error state. In certain embodiments, a system, apparatus, or method may respond to satisfaction of a critical threshold by proactively alerting another system, host, or controller. In one embodiment, in response to a zone metric 610 satisfying an alert threshold 624, the zone manager 600 and/or storage controller 104 may trigger an interrupt to signal the condition to a host 108.

The signaling circuit 606 may serve to relay commands and information between the zone manager 600 and the host 108. In one embodiment, the signaling circuit 606 may be part of the storage controller 104. The signaling circuit 606 may be configured to notify a host 108 of the zone health 628 for one or more zones, or for a group of zones in response to the zone metric 610 for the zone(s) satisfying the alert threshold 624. In one embodiment, the zone metric is representative of the zone health such that the signaling circuit 606 notifies the host 108 of zone health by providing the zone metric.

In certain embodiments, together with the zone health, the signaling circuit 606 may also send metadata 630 to the host 108. The metadata 630 may provide additional data about one or more physical erase blocks, one or more zones, or a combination of these. In one embodiment, the metadata 630 may provide additional data about the one or more zones for which one or more zone health values satisfied the alert threshold 624. In one embodiment, the metadata 630 comprises the zone metric 610.

In one embodiment, the signaling circuit 606 notifies the host 108 proactively, without waiting for a zone command or other command from the host 108. In another embodiment, the signaling circuit 606 may notify the host 108 only in response to a zone command or other command or instruction from the host 108.

The signaling circuit 606 may receive notification of such an alert condition from the monitor circuit 602 and/or evaluation circuit 604. In response to notification of an alert condition, the signaling circuit 606 may send the metadata 630 for the indicated zones to the host 108.

In certain embodiments, the zone manager 600 acts without instructions from the host 108 if the condition of a zone justifies such steps, such as when a zone metric satisfies a critical threshold. Such a condition is referred to herein as a critical condition. The remediation circuit 608 may be configured to implement one or more countermeasures 634 in response to the zone metric satisfying the critical threshold 626. In some embodiments, the host 108 may receive notification of a critical condition concurrent with implementation of a countermeasure and/or after the countermeasure is implemented.

Once the host 108 has notice of the zone metric, the host 108 may determine how to respond and handle the situation. The host 108 is in a position to make decisions about handling the zone metric because the host 108 may also be aware of the type of data on each zone, the access frequency for data of each zone, the expected life for data on each zone, the value of the data on each zone, and the like. Thus, in certain embodiments, the host 108 determines how to respond, and may issue a countermeasure command 632 to the zone manager 600. The remediation circuit 608 may receive, handle, and respond to the countermeasure command 632. “Countermeasure command” refers to a storage command configured to implement a countermeasure to mitigate, or reverse, deterioration of a zone and/or deteriorating zone health.

In certain embodiments, the remediation circuit 608 implements the countermeasure in response to the countermeasure command 632. In another embodiment, the remediation circuit 608 coordinates with the storage controller 104 and/or other components of the storage controller 104 to implement the countermeasure command 632. In one embodiment, rather than wait for a countermeasure command 632, the remediation circuit 608 may implement a countermeasure in response to the zone metric satisfying a critical threshold 626.

FIG. 7 illustrates a ZNS storage system 700 in accordance with one embodiment. The ZNS storage system 700 may comprise similar storage components to those described with regard to FIG. 1, FIG. 5, and FIG. 6. The ZNS storage system 700 may include a storage device 102 that comprises a storage controller 104, a volatile memory 702, and a non-volatile memory array 704 comprising at least one memory die 106. The ZNS storage system 700 may further comprise a temperature manager 706 and a health manager 708, implemented within the storage controller 104. Those of skill in the art will appreciate that these components may be incorporated within other parts of the storage device 102 or may be carried out by the host 108 in some systems.

The storage controller 104 may be coupled to the volatile memory 702 and the non-volatile memory array 704 via a bus 124. The storage controller 104 may be configured to interface with one or more hosts 108 and operate a plurality of zones within the non-volatile memory array 704 based on a zoned storage device standard 716. Since the storage device 102 complies with the zoned storage device standard 716, the storage controller 104 communicates with the host 108 over data bus 122 using a protocol that adheres to the zoned storage device standard 716. The storage controller 104 may comprise a zone manager 600 as illustrated in FIG. 6, as well as a temperature manager 706 and a health manager 708.

The temperature manager 706 may be configured to monitor a cross temperature metric for each physical erase block of each zone, by way of one or more temperature sensors 614 coupled to each memory die 106. The temperature manager 706 may be further configured to notify the zone manager 600 in response to the cross-temperature metric for one or more of the zones satisfying an alert threshold. The temperature manager 706 may notify the zone manager 600 in relation to a cross temperature metric for both open zones and closed zones, or either separately.

In one embodiment, the temperature manager 706 may track an average temperature for the zones. In another embodiment, the temperature manager 706 may track each physical erase block of each zone for cross temperature conditions. Alert thresholds may be defined such that there is one for each level, health, cross temperature, zone block metric, and/or the like.

The health manager 708 may be configured to monitor a block health metric for each physical erase block of each zone. The health manager 708 may be further configured to notify the zone manager 600 in response to the block health metric for the one or more of the zones satisfying the alert threshold.

The zone manager 600 may be configured to interface with the host 108 and to manage a plurality of zones within the non-volatile memory array 704 by way of a zoned storage device standard.

“Zoned storage device standard” refers to a technical standard for implementing a zoned storage device. The standard may be established by a group of companies or a standards setting organization (at a regional, national, or international level). In one embodiment, defined by a zoned storage device standard, a zone comprises one or more memory cells organized and operated according to a storage standard, architecture, or design, including, but not limited to, the Small Computer System Interface (SCSI) Zoned block Commands (ZBC) standard, the Zoned Device Advanced Technology Attachment (ATA) standards on Shingled Magnetic Recording (SMR) hard disks, the non-volatile memory Express (NVMe) Zoned Namespaces, (ZNS) standard, the OpenChannel Solid-State Drive (SSD) architecture, or the like. Examples of these standards architectures, or designs is available at the websites zonedstorage.io and lightnvm.io.

The zone manager 600 may be configured to determine a zone metric based at least in part on one of the cross-temperature metrics from the temperature manager 706 and the block health metrics from the health manager 708. The zone manager 600 may be further configured to report the cross-temperature metric for a zone to the host 108 in response to a read command 710 for the zone from the host 108. “Read command” refers to a type of storage command that reads data from memory cells.

In some embodiments, the zone manager 600 may be configured to report the zone metric in response to any storage command 712 from the host. “Storage command” refers to any command relating with a storage operation. Examples of storage commands include, but are not limited to, read commands, write commands, maintenance commands, diagnostic commands, test mode commands, and any other command a storage controller may receive from a host or issue to another component, device, or system.

The zone manager 600 may be configured to implement one or more countermeasures on one or more zones in response to a report of the zone metric to the host 108 configured to manage the zones. Countermeasures may include reassigning zones in order balance the relative or average health of physical erase blocks making up a zone or relocating or implementing a cooling process for zones exhibiting cross temperature issues. In certain embodiments, the cooling process may include activating certain active cooling components such as one or more fans and/or a liquid cooling system.

In some embodiments, when an alert threshold is satisfied and countermeasures are requested as a result, the storage controller 104 may be configured to throttle Input/Output (IO) operations 714 with the host 108. This throttling may be maintained until the zone manager 600 confirms that the zone metric no longer meets the alert threshold, indicating that the countermeasures requested by the host 108 has been successful. “Input/Output (IO) operation” refers to a storage operation that results in either moving data into a memory die (Input) or moving data out (Output) of a memory die. One example of an input storage operation is the storing or programming of data to memory cells of one or more memory die. One example of an output storage operation is the reading or sensing of data from memory cells of one or more memory die.

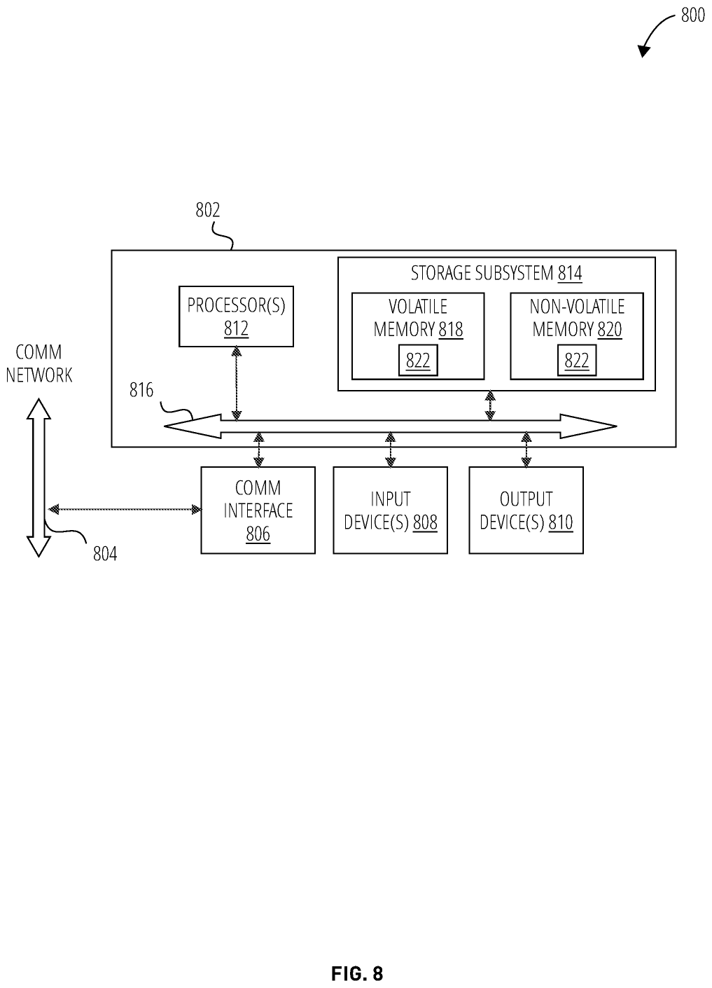

FIG. 8 is an example block diagram of a computing device 800 that may incorporate embodiments of the solution. FIG. 8 is merely illustrative of a machine system to carry out aspects of the technical processes described herein and does not limit the scope of the claims. One of ordinary skill in the art would recognize other variations, modifications, and alternatives. In certain embodiments, the computing device 800 includes a data processing system 802, a communication network 804, communication network interface 806, input device(s) 808, output device(s) 810, and the like.

As depicted in FIG. 8, the data processing system 802 may include one or more processor(s) 812 and a storage subsystem 814. “Processor” refers to any circuitry, component, chip, die, package, or module configured to receive, interpret, decode, and execute machine instructions. Examples of a processor may include, but are not limited to, a central processing unit, a general-purpose processor, an application-specific processor, a graphics processing unit (GPU), a field programmable gate array (FPGA), Application Specific Integrated Circuit (ASIC), System on a Chip (SoC), virtual processor, processor core, and the like.

The processor(s) 812 communicate with a number of peripheral devices via a bus subsystem 816. These peripheral devices may include input device(s) 808, output device(s) 810, communication network interface 806, and the storage subsystem 814. The storage subsystem 814, in one embodiment, comprises one or more storage devices and/or one or more memory devices.

“Storage device” refers to any hardware, system, sub-system, circuit, component, module, non-volatile memory media, hard disk drive, storage array, device, or apparatus configured, programmed, designed, or engineered to store data for a period of time and retain the data in the storage device while the storage device is not using power from a power supply. Examples of storage devices include, but are not limited to, a hard disk drive, FLASH memory, MRAM memory, a Solid-State storage device, Just a Bunch Of Disks (JBOD), Just a Bunch Of Flash (JBOF), an external hard disk, an internal hard disk, and the like. “Memory” refers to any hardware, circuit, component, module, logic, device, or apparatus configured, programmed, designed, arranged, or engineered to retain data. Certain types of memory require availability of a constant power source to store and retain the data. Other types of memory retain and/or store the data when a power source is unavailable.

In one embodiment, the storage subsystem 814 includes a volatile memory 818 and a non-volatile memory 820. The volatile memory 818 and/or the non-volatile memory 820 may store computer-executable instructions that alone or together form logic 822 that when applied to, and executed by, the processor(s) 812 implement embodiments of the processes disclosed herein.

“Volatile memory” refers to a shorthand name for volatile memory media. In certain embodiments, volatile memory refers to the volatile memory media and the logic, controllers, processor(s), state machine(s), and/or other periphery circuits that manage the volatile memory media and provide access to the volatile memory media.

“Volatile memory media” refers to any hardware, device, component, element, or circuit configured to maintain an alterable physical characteristic used to represent a binary value of zero or one for which the alterable physical characteristic reverts to a default state that no longer represents the binary value when a primary power source is removed or unless a primary power source is used to refresh the represented binary value. Examples of volatile memory media include but are not limited to dynamic random-access memory (DRAM), static random-access memory (SRAM), double data rate random-access memory (DDR RAM) or other random-access solid-state memory.

While the volatile memory media is referred to herein as “memory media,” in various embodiments, the volatile memory media may more generally be referred to as volatile memory.

In certain embodiments, data stored in volatile memory media is addressable at a byte level which means that the data in the volatile memory media is organized into bytes (8 bits) of data that each have a unique address, such as a logical address.

“Non-volatile memory” refers to shorthand name for non-volatile memory media. In certain embodiments, non-volatile memory media refers to the non-volatile memory media and the logic, controllers, processor(s), state machine(s), and/or other periphery circuits that manage the non-volatile memory media and provide access to the non-volatile memory media.

“Logic” refers to machine memory circuits, non-transitory machine readable media, and/or circuitry which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter).

The input device(s) 808 include devices and mechanisms for inputting information to the data processing system 802. These may include a keyboard, a keypad, a touch screen incorporated into a graphical user interface, audio input devices such as voice recognition systems, microphones, and other types of input devices. In various embodiments, the input device(s) 808 may be embodied as a computer mouse, a trackball, a track pad, a joystick, wireless remote, drawing tablet, voice command system, eye tracking system, and the like. The input device(s) 808 typically allow a user to select objects, icons, control areas, text and the like that appear on a graphical user interface via a command such as a click of a button or the like.

The output device(s) 810 include devices and mechanisms for outputting information from the data processing system 802. These may include a graphical user interface, speakers, printers, infrared LEDs, and so on, as well understood in the art. In certain embodiments, a graphical user interface is coupled to the bus subsystem 816 directly by way of a wired connection. In other embodiments, the graphical user interface couples to the data processing system 802 by way of the communication network interface 806. For example, the graphical user interface may comprise a command line interface on a separate computing device 800 such as desktop, server, or mobile device.

The communication network interface 806 provides an interface to communication networks (e.g., communication network 804) and devices external to the data processing system 802. The communication network interface 806 may serve as an interface for receiving data from and transmitting data to other systems. Embodiments of the communication network interface 806 may include an Ethernet interface, a modem (telephone, satellite, cable, ISDN), (asynchronous) digital subscriber line (DSL), FireWire, USB, a wireless communication interface such as Bluetooth or WiFi, a near field communication wireless interface, a cellular interface, and the like.

The communication network interface 806 may be coupled to the communication network 804 via an antenna, a cable, or the like. In some embodiments, the communication network interface 806 may be physically integrated on a circuit board of the data processing system 802, or in some cases may be implemented in software or firmware, such as “soft modems”, or the like.

The computing device 800 may include logic that enables communications over a network using protocols such as HTTP, TCP/IP, RTP/RTSP, IPX, UDP and the like.

The volatile memory 818 and the non-volatile memory 820 are examples of tangible media configured to store computer readable data and instructions to implement various embodiments of the processes described herein. Other types of tangible media include removable memory (e.g., pluggable USB memory devices, mobile device SIM cards), optical storage media such as CD-ROMS, DVDs, semiconductor memories such as flash memories, non-transitory read-only-memories (ROMS), battery-backed volatile memories, networked storage devices, and the like. The volatile memory 818 and the non-volatile memory 820 may be configured to store the basic programming and data constructs that provide the functionality of the disclosed processes and other embodiments thereof that fall within the scope of the present invention.

Logic 822 that implements one or more parts of embodiments of the solution may be stored in the volatile memory 818 and/or the non-volatile memory 820. Logic 822 may be read from the volatile memory 818 and/or non-volatile memory 820 and executed by the processor(s) 812. The volatile memory 818 and the non-volatile memory 820 may also provide a repository for storing data used by the logic 822.

The volatile memory 818 and the non-volatile memory 820 may include a number of memories including a main random-access memory (RAM) for storage of instructions and data during program execution and a read only memory (ROM) in which read-only non-transitory instructions are stored. The volatile memory 818 and the non-volatile memory 820 may include a file storage subsystem providing persistent (non-volatile) storage for program and data files. The volatile memory 818 and the non-volatile memory 820 may include removable storage systems, such as removable flash memory.

The bus subsystem 816 provides a mechanism for enabling the various components and subsystems of data processing system 802 communicate with each other as intended. Although the communication network interface 806 is depicted schematically as a single bus, some embodiments of the bus subsystem 816 may utilize multiple distinct busses.

It will be readily apparent to one of ordinary skill in the art that the computing device 800 may be a device such as a smartphone, a desktop computer, a laptop computer, a rack-mounted computer system, a computer server, or a tablet computer device. As commonly known in the art, the computing device 800 may be implemented as a collection of multiple networked computing devices. Further, the computing device 800 will typically include operating system logic (not illustrated) the types and nature of which are well known in the art.

Terms used herein should be accorded their ordinary meaning in the relevant arts, or the meaning indicated by their use in context, but if an express definition is provided, that meaning controls.

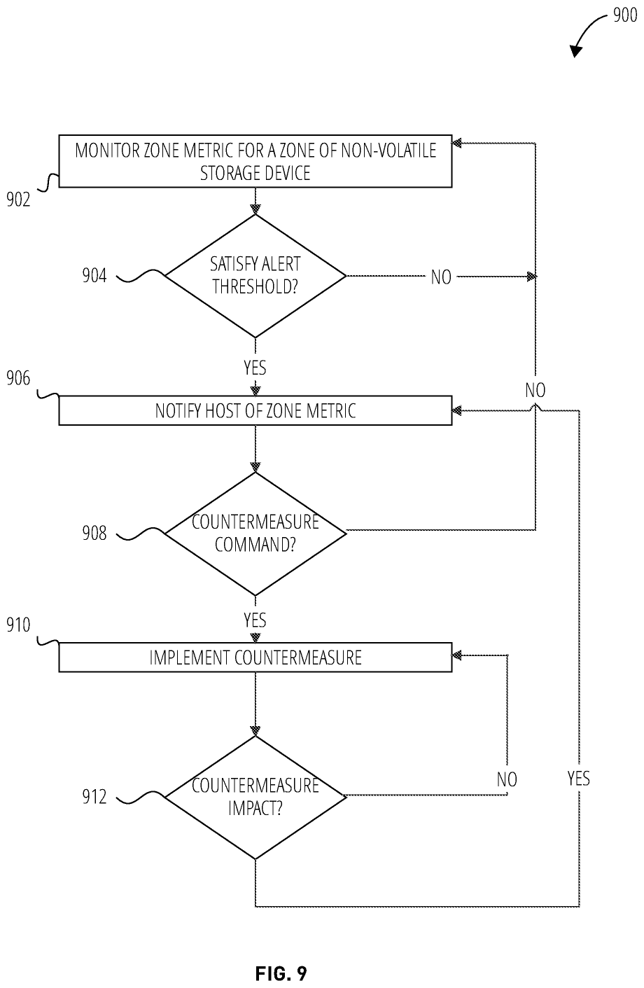

FIG. 9 illustrates a method 900 in accordance with one embodiment. Starting in block 902, the method monitors a zone metric for a zone of a non-volatile storage device. In one embodiment, the zone metric may be updated after a period of time (e.g., five minutes). This period of time may be shorter when a zone manager 600 has notified a host of a zone metric that satisfies an alert threshold. In another embodiment, the zone metric may be updated after a certain number of events, such as read commands or erase storage operations, or the like. In one embodiment, the zone manager 600 may notify the host of an updated zone metric when the change in the zone block metric satisfies a change threshold. A change threshold and notification of an updated zone metric may be done when a zone metric has previously satisfied an alert threshold.

In certain embodiments, a step of updating a zone metric may be part of the monitoring in block 902. In other embodiments, the step of updating a zone metric may be another step in the process. The zone metric may be a cross temperature metric, a block health metric, or some combination thereof.

At decision block 904 a determination is made whether the zone metric satisfies an alert threshold. If not, the method returns to block 902 to monitor the zone metric. If so, the method proceeds to block 906.

At block 906, the method notifies a host of about the zone metric. How a storage controller, or other component such as a zone manager 600, notifies the host may vary depending on the embodiment. In one embodiment, the storage controller may send a message or signal to the host. In one embodiment, the storage controller may send an alert or interrupt to the host. In one embodiment, the storage controller may activate a configuration flag that informs the host that an alert threshold has been satisfied. In one embodiment, the storage controller may log that an alert threshold has been satisfied and the host may get the information by processing the log.

Furthermore, the form, format, and substance of how a zone manager 600 and/or storage controller notifies a host may vary in different embodiments. In one embodiment, notifying the host may comprise sending metadata associated with the zone metric satisfying the alert threshold. In one embodiment, the metadata may relate only to the zone associated with the zone metric that satisfies the alert threshold. In another embodiment, the metadata may include one or more zone metrics for a plurality of zones (some that satisfy the alert threshold and some that may not satisfy the alert threshold).

In certain embodiments, the metadata sent may comprise a cross temperature for the zone, an average cross temperature for open zones of the non-volatile storage device, a temperature change rate, an average program erase count for the zone, an uncorrectable bit error rate (UBER) for the zone, a fail bit count for the zone, a charge leak rate, and the like.

In another embodiment, notifying the host may further comprise proposing a countermeasure for the zone, the proposed countermeasure may be based on one or more physical characteristics of one or more erase blocks of the non-volatile storage device. For example, the zone manager and/or storage controller may propose a countermeasure of closing a zone (even if the zone is not yet full of data) based on a physical characteristic such as greater than 50% of the physical erase blocks of the zone exhibiting a fail bit count above a certain threshold.

In embodiments in which the zone metric comprises a cross temperature metric, proposed countermeasures may be selected from a group of measures consisting of closing the zone, actively changing a temperature of erase blocks within the zone, relocating data of the zone to another zone, adjusting the alert threshold, managing one or more physical erase blocks of the zone using separate Cell Voltage Distribution (CVD) tables, and/or taking no action.

When the zone metric comprises a block health metric and an issue with zone health is noted, countermeasures may include adjusting zone assignments and relocating data of the problematic zone to another zone. Zones may be assigned such that each zone has a similar mean health value, based on the health of the physical erase blocks they contain. Physical erase block allocation per zone may alternately be adjusted to minimize a difference in health between erase blocks within a zone, giving each zone a more equalized block health metric. In one embodiment, the device may be configured with a first zone having maximum block health metric scores, a following zone with the next most healthy unallocated blocks, and so on.

Notifying the host may include identifying a ranked set of countermeasures. “Ranked set of countermeasures” refers to a set of countermeasures that a host may implement to mitigate a situation in which two or more zones have a value or setting for a zone metric that is outside an acceptable range or different from an acceptable value. In one embodiment, the set of countermeasures is ranked based on one or more attributes associated with each countermeasure.

For example, the set of countermeasures may be ranked based on which ones are expected to impose a least amount of wear on memory cells of a zone, or which ones are expected to impose the least performance impact. In another example, the set of countermeasures may be ranked based on which ones are expected to mitigate an unacceptable zone metric condition. In still another example, the set of countermeasures may be ranked based on which ones are expected to mitigate write amplification within the non-volatile storage device (storage device 102). Of course, in one embodiment, a host may implement its own set of countermeasure independent of the storage device 102. For example, a host may restrict, or redirect, write storage operations directed to the storage device 102.

Under the zoned storage device standard, the host is the master and the storage device 102 is a slave. However, if the host decides to implement a countermeasure using the storage device 102, the host may send a countermeasure command. The method 900, includes the decision block 908 in which the zone manager and/or storage controller check to see if a countermeasure command has been received. If not, monitoring of one or more zone metrics continues with block 902. If so, then the method 900 implements (block 910) the countermeasure indicated in the countermeasure command.

In certain embodiments, once a countermeasure is implemented, the method 900 may end. Alternatively, or in addition, once a countermeasure is implemented, or at least initiated, a certain period of time may be required to determine whether the countermeasure has made an impact and changed the zone metric in a positive way. The zone may be monitored in decision block 912 to detect an impact resulting from the countermeasure. In some embodiments, the host may be notified regarding the impact resulting from the countermeasure, if any (block 906).

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc., are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

What is claimed is:

1. An apparatus, comprising:
a zone manager comprising:
a monitor circuit configured to monitor a zone metric for each zone of a non-volatile storage device;
an evaluation circuit configured to determine a zone health for each zone based on the zone metric; and
a signaling circuit configured to notify a host of the zone health for one or more zones, in response to the zone metric of the one or more zones satisfying an alert threshold.

2. The apparatus of claim 1, wherein the signaling circuit is further configured to notify the host of the zone health by sending metadata for the one or more zones.

3. The apparatus of claim 1, further comprising a remediation circuit configured to implement a countermeasure in response to the zone metric satisfying a critical threshold.

4. The apparatus of claim 1, further comprising a remediation circuit configured to implement a countermeasure in response to a countermeasure command from the host.

5. The apparatus of claim 1, wherein the zone metric comprises one or more of a block health metric for each zone and a cross temperature metric for each zone.

6. The apparatus of claim 1, wherein the evaluation circuit is configured to:
receive a temperature from a temperature sensor configured to monitor a plurality of physical erase blocks of each zone,
determine a wear level for each physical erase block of each zone,
determine a cross temperature metric based on the temperature and a programmed temperature,
determine a block health metric based on the wear level, and
determine the zone metric based on both the block health metric and the cross-temperature metric.

7. A system, comprising:
volatile memory;
a non-volatile memory array comprising a plurality of memory dies; and
a storage controller coupled to the volatile memory and to the non-volatile memory array, the storage controller comprising:
a zone manager configured to interface with a host and to manage a plurality of zones within the non-volatile memory array by way of a zoned storage device standard;
a temperature manager configured to:
monitor a cross temperature metric for each physical erase block of each zone, by way of at least one temperature sensor coupled to each memory die; and
notify the zone manager in response to the cross-temperature metric for one or more of the zones satisfying an alert threshold;
a health manager configured to:
monitor a block health metric for each physical erase block of each zone; and
notify the zone manager in response to the block health metric for the one or more of the zones satisfying the alert threshold;
wherein the zone manager is configured to determine a zone metric based at least in part on one of the cross-temperature metric from the temperature manager and the block health metric from the health manager; and
wherein the zone manager is configured implement one or more countermeasures on one or more zones in response to a report of the zone metric to the host configured to manage the zones.

8. The system of claim 7, wherein the zone manager is configured to report the zone metric in response to a storage command from the host.

9. The system of claim 7, wherein the storage controller is configured to throttle Input/Output (IO) operations with the host, until the zone manager confirms that the zone metric fails to satisfy the alert threshold indicating success of the countermeasure requested by the host.

10. The system of claim 7, wherein the zone manager is configured to report the cross-temperature metric for a zone to the host in response to a read command for the zone from the host.

11. A method, comprising:
monitoring a zone metric for a zone of a non-volatile storage device;
notifying a host of the zone metric, in response to the zone metric satisfying an alert threshold; and
implementing a countermeasure in response to a countermeasure command from the host.

12. The method of claim 11, further comprising:
monitoring the zone for an impact from the countermeasure, and
notifying the host regarding the impact from the countermeasure.

13. The method of claim 11, wherein notifying the host comprises sending metadata associated with the zone metric satisfying the alert threshold.

14. The method of claim 13, wherein the metadata comprises data selected from a group comprising a cross temperature for the zone, an average cross temperature for open zones of the non-volatile storage device, a temperature change rate, an average program erase count for the zone, an uncorrectable bit error rate (UBER) for the zone, a fail bit count for the zone, and a charge leak rate.

15. The method of claim 11, wherein notifying the host further comprises:
proposing a countermeasure for the zone, the proposed countermeasure based on one or more physical characteristics of one or more erase blocks of the non-volatile storage device.

16. The method of claim 11, wherein notifying the host further comprises identifying a ranked set of countermeasures, the ranked set of countermeasures ranked to mitigate write amplification within the non-volatile storage device.

17. The method of claim 11, wherein the zone metric comprises a cross temperature metric and the countermeasure comprises a countermeasure selected from a group consisting of closing the zone, actively changing a temperature of erase blocks within the zone, relocating data of the zone to another zone, adjusting the alert threshold, managing one or more physical erase blocks of the zone using separate Cell Voltage Distribution (CVD) tables, and taking no action.

18. The method of claim 11, further comprising:
updating the zone metric after a period of time, and
notifying the host of the updated zone metric in response to a change in the zone block metric satisfying a change threshold.

19. The method of claim 11, wherein the zone metric comprises a block health metric for the zone.

20. The method of claim 11, wherein the zone metric comprises a cross temperature metric for the zone.
